(19) United States
(12) Patent Application Publication
(10) Pub. No.: US 2024/0162267 A1
(43) Pub. Date: May 16, 2024

(54) MICROMINIATURE IMAGE ACQUISITION AND PROCESSING SYSTEM PACKAGING STRUCTURE AND PREPARATION METHOD THEREOF

(71) Applicant: JCET GROUP CO., LTD., JIANGSU (CN)

(72) Inventors: Jianyong Wu, JIANGSU (CN); Yaojian Lin, JIANGSU (CN); Danfeng Yang, JIANGSU (CN); Chen Xu, JIANGSU (CN); Wei Yan, JIANGSU (CN)

(73) Assignee: JCET GROUP CO., LTD., JIANGSU (CN)

(21) Appl. No.: 18/506,008

(22) Filed: Nov. 9, 2023

(30) Foreign Application Priority Data
Nov. 11, 2022 (CN) 202211411905.9

(51) Int. Cl. H01L 27/146

(52) U.S. Cl. CPC H01L 27/14634; H01L 27/14618; H01L 27/14627; H01L 27/14632; H01L 27/14636; H01L 27/14643; H01L 27/14685; H01L 27/14687; H01L 27/14689; H01L 27/1469

(57) ABSTRACT

The present invention discloses a microminiature image acquisition and processing system package structure and a preparation method thereof. This structure includes optical coated glass, a CMOS chip, a wafer Re-Distribution Layer and a molding layer, the first surface of the CMOS chip is provided with a photosensitive and microlens region and a metal bonding pad, and a through-silicon via is etched in a second surface of the CMOS chip until it extends to the metal bonding pad on the first surface; the wafer Re-Distribution Layer covers the second surface of the CMOS chip and extends to the through-silicon via. The structure and the method of the present invention are integrated with wafer-level package and SIP integrated package technologies to achieve single package of the whole device, thereby greatly reducing the system complexity and power consumption, reducing the overall product size and signal path, and improving the image anti-interference capability.

### CROSS-REFERENCE TO RELATED APPLICATION

This application claims the priority benefit of China application serial no. 202211411905.9, filed on Nov. 11, 2022. The entirety of the above-mentioned patent application is hereby incorporated by reference herein and made a part of this specification.

### BACKGROUND

### Technical Field

The present invention relates to the technical field of semiconductor package, and more particularly to a microminiature image acquisition and processing system package and method for manufacturing the same.

### Description of Related Art

An image acquisition and processing system generally includes an image sensor, an image signal processor (ISP), an image encoder, and a master controller. However, a camera module only provides image acquisition, and outputs digital or analog image information to a back-end ISP or a codec chip for image optimization and coding compression, and a master control chip controls final data transmission and storage. In the image acquisition and processing system, the image acquisition, processing, coding compression and system control in the conventional scheme are completed by different chips and different modules, including at least two chips or two modules. This invention provides a solution of a package-level highly integrated system-on-a-chip or module.

In an integration direction of the traditional image processing system, a master control chip generally integrates an ISP and a coder to simplify the entire image acquisition and processing system. However, this solution often needs to consider the versatility of the master control SOC chip system, such that the master control SOC chip system is too large for some applications, high in power consumption and large package size. In addition, image sensors still exist in an independent chip package, which makes the entire system complex and is not conducive to application in the field of microelectronics and wearable products.

### SUMMARY

In view of the defects of the prior technology, the present invention provides a microminiature image acquisition and processing system package and method for manufacturing the same.

In order to solve the aforementioned technical problems, the present invention adopts the following technical solutions.

A microminiature image acquisition and processing system package includes:
optical coated glass, a first surface of the optical coated glass being provided with a protective film, a cofferdam being formed around a second surface of the optical coated glass;
a CMOS chip, a first surface of the CMOS chip being provided with a photosensitive and microlens region and a metal bonding pad, a through-silicon via being etched in a second surface of the CMOS chip until it extends to the metal bonding pad on the first surface, the cofferdam being seamlessly connected to the metal bonding pad and an edge region around the CMOS chip through an adhesive film and covering the first surface of the CMOS chip to form a cavity, the photosensitive and microlens region being located in the cavity;
a wafer Re-Distribution Layer, a first layer of the wafer Re-Distribution Layer covering the second surface of the CMOS chip and extending to the through-silicon via region, an image processor and coder, a master controller, a power supply and a connecting board being disposed on the outermost layer of the wafer Re-Distribution Layer; and a molding layer, the molding layer being configured to perform molding on the second surface of the CMOS chip, a solder ball being disposed outside the molding layer and corresponding to the position of the connecting board with each other.

In some embodiments, the wafer Re-Distribution Layer includes passivation layers and metal layers that, which are bonded to each other; the number of the passivation layers is greater than that of the metal layers by 1; and
the first layer of the wafer Re-Distribution Layer is the passivation layer, and the outermost layer of the wafer Re-Distribution Layer is the passivation layer.

In some embodiments, there are two metal layers, i.e., the first metal layer and the second metal layer; and there are three passivation layers, i.e., the first passivation layer, the second passivation layer and the third passivation layer; and
the first passivation layer covers the second surface of the CMOS chip and extends to the through silicon via region, the first metal layer covers the first passivation layer and extends into the through silicon via so that the first surface and the second surface of the CMOS chip are electrically connected, and the second passivation layer, the second metal layer and the third passivation layer sequentially cover the first metal layer.

In some embodiments, three or more metal layers and four or more passivation layers are provided.

In some embodiments, the protective film is made of a metal, a polymer or a mixture of the metal and the polymer.

In some embodiments, the connecting board is higher than the image processor and coder, the master controller, the Flash, the power supply and other units.

In some embodiments, the image processor and coder, the master controller, the Flash, the power supply and other units are designed by means of flip chip or wire bonding and stacking, and are communicated by the metal layers or by means of metal wire bonding.

A method for the microminiature image acquisition and processing system package includes the following steps:
providing optical coated glass, a first surface of the optical coated glass being provided with a protective film, a cofferdam being formed around a second surface of the optical coated glass; providing a CMOS chip, a first surface of the CMOS chip being provided with a photosensitive and microlens region and a metal bonding pad, a through-silicon via being etched in a second surface of the CMOS chip until it extends to the metal bonding pad on the first surface, the cofferdam being seamlessly connected to the metal bonding pad and an edge region around the CMOS chip through an adhesive film and covering the first surface of the CMOS chip to form a cavity, the photosensitive and microlens region being located in the cavity;
forming a wafer Re-Distribution Layer, the first layer of the wafer Re-Distribution Layer covering the second surface of the CMOS chip and extending to the through-silicon via region, an image processor and coder, a master controller, a Flash, a power supply and a connecting board being disposed on the outermost layer of the wafer Re-Distribution Layer; and
forming a molding layer, the molding layer being configured to perform encapsulating on the second surface of the CMOS chip, a solder ball being disposed outside the molding layer and corresponding to the position of the connecting board with each other.

In some embodiments, the wafer Re-Distribution Layer includes passivation layers and metal layers that, which are bonded to each other; the number of the passivation layers is greater than that of the metal layers by 1; and
the first layer of the wafer Re-Distribution Layer is the passivation layer, and the outermost layer of the wafer Re-Distribution Layer is the passivation layer.

In some embodiments, there are two metal layers, i.e., the first metal layer and the second metal layer; and there are three passivation layers, i.e., the first passivation layer, the second passivation layer and the third passivation layer; and
the first passivation layer covers the second surface of the CMOS chip and extends to the through silicon via region, the first metal layer covers the first passivation layer and extends into the through silicon via, so that the first surface and the second surface of the CMOS chip are electrically connected, and the second passivation layer, the second metal layer and the third passivation layer sequentially cover the first metal layer.

In some embodiments, the second surface of the CMOS chip is passivated and patterned for the first time to form the first passivation layer;
the first metal layer is generated on the first passivation layer;
the first metal layer is then passivated and patterned for the second time to form the second passivation layer;
the second metal layer is generated on the second passivation layer; and
the second metal layer is passivated and patterned for the third time to form the third passivation layer.

In some embodiments, the image processor and coder, the master controller, the power supply and the connecting board are mounted on the outermost layer of the wafer Re-Distribution Layer or connected there to via a conductive structure.

In some embodiments, the image processor and coder, the master controller, the power supply and other units are designed by means of flip chip or wire bonding and stacking, and are communicated by the metal layers or by means of metal wire bonding.

In some embodiments, the method further includes the following steps:
performing film-insert encapsulating or conventional encapsulating on the molding layer and then grinding to expose the connecting board; and
mounting the solder ball on the connecting board, cutting the plate, and performing final test.

Due to the embodiments of the aforementioned technical solutions, the present invention has significant technical effects.

The present invention adopts a scheme in which the CMOS chip, the image processor, the coder and a control system are packaged and integrated, and the control system is used for system control and data transmission, so the structure has no high requirements for system resources, and is designed to complete relevant functions by using a low-power-consumption microprocessor, thereby reducing the overhead of the entire system.

Through the package technology, the CMOS chip, the image processor (specifically, an image signal processor ISP), the coder (specifically, an image coder), the master controller, the Flash, the power supply, a clock and other desired extended functions are integrated to form the package. A system formed by the entire package can achieve a single design, reduce the overall product size and signal path, improve the anti-interference ability of an image, and greatly reduce the complexity and power consumption of the system. Therefore, the system is compact in structure, and thus can be widely used in application scenarios with strict requirements for the size of an image module, such as medical capsule cameras, industrial micro cameras or wearable products.

### BRIEF DESCRIPTION OF THE DRAWINGS

To describe the embodiments of the present disclosure or the technical solutions in the prior art more clearly, the following briefly introduces the accompanying drawings required for describing the embodiments or the descriptions in the prior technology. Apparently, the accompanying drawings in the following description show merely some embodiments of the present disclosure, and a person of ordinary skill in the art may still derive other drawings from these accompanying drawings without creative efforts.

FIG. 1 is an overall schematic structural diagram of a package structure.

FIG. 2 is an overall schematic structural diagram of another embodiment of the package structure.

FIGS. 3 to 15 are schematic diagrams of a preparation method.

### DESCRIPTION OF THE EMBODIMENTS

The present invention is further elaborated in conjunction with embodiments. The following embodiments are intended to explain the present invention, but the present invention is not limited to the following embodiments.

In the prior technology, for wearable electronic products such as medical capsule endoscopes, industrial miniature cameras, AR/VR glasses, smart watches, police communications or mine safety modules, owing to strict requirements for volume and power consumption, it is necessary to design a microminiature image acquisition and processing system package, which not only has a compact structure but also can greatly improve the flexibility of the entire image acquisition and processing system and the convenience of structural design.

### Exemplary Structure

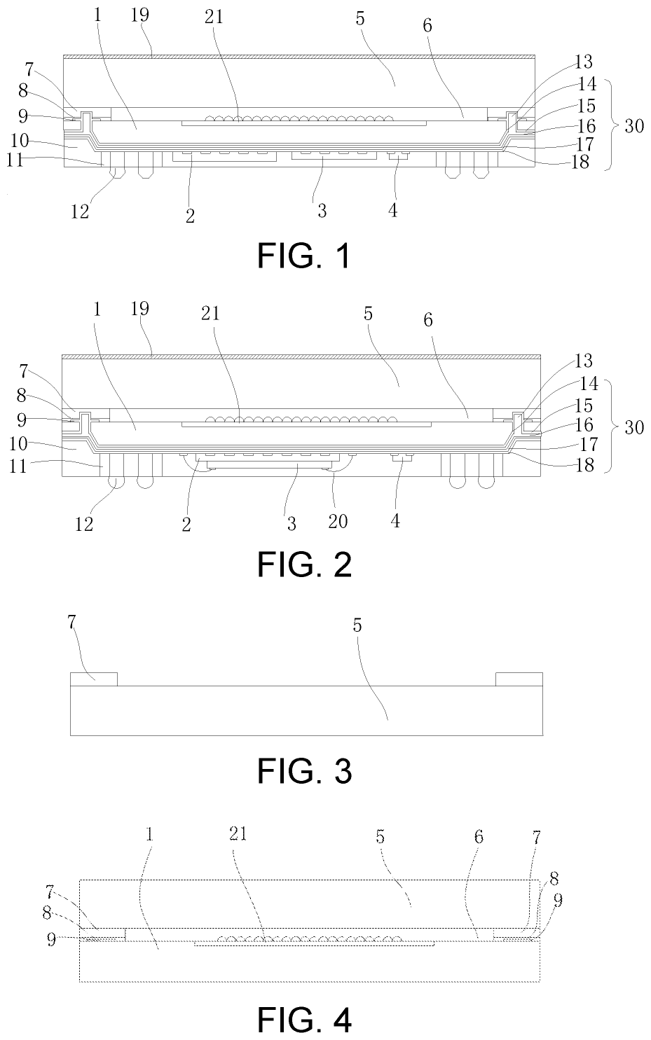

As shown in FIG. 1, a microminiature image acquisition and processing system package structure includes: optical coated glass 5, a first surface of the optical coated glass 5 being provided with a protective film 9, a cofferdam 7 being formed around a second surface of the optical coated glass 5; a CMOS chip 1, a first surface of the CMOS chip 1 being provided with a photosensitive and microlens region 21 and a metal bonding pad 9, a through-silicon via 13 being etched in a second surface of the CMOS chip 1 until it extends to the metal bonding pad 9, the cofferdam 7 being seamlessly connected to the metal bonding pad 9 and an edge region around the CMOS chip 1 through an adhesive film 8 and covering the first surface of the CMOS chip 1 to form a cavity 6, the photosensitive and microlens region 21 being located in the cavity 6; a wafer Re-Distribution Layer 30, a first layer of the wafer Re-Distribution Layer 30 covering the second surface of the CMOS chip 1 and extending to the through-silicon via 13 region, an image processor and coder 2, a master controller 3, a power supply 4 and a connecting board 11 being disposed on the outermost layer of the wafer Re-Distribution Layer 30; and a molding layer 10, the molding layer 10 being configured to perform molding on the second surface of the CMOS chip 1, a solder ball 12 being disposed outside the molding layer 10 and corresponding to the position of the connecting board 11 with each other. Of course, the solder ball may also be a pad or bump, as long as it can be welded, while its shape is not limited.

The photosensitive and microlens region 21 is located on the first surface of the CMOS chip 1, and the second surface of the CMOS chip 1, in addition to being provided with the master controller 3, the image processor and coder 2 and the power supply 4, is also provided with other necessary units, such as a Flash, a clock, a discrete device and other units, which can be set as needed. The components are mainly packaged in WLP or FC to save a mounting area. The power supply 4, the clock, the discrete device, a resistance-capacitance device and other units are packaged in small chip packages. The master controller 3 realizes the control and management of other functional chips and image sensors through a control bus (I2C bus/SIP bus/GPIO), and provides an external data interface to send optimized and coded image information. The data bus, the control bus, the power supply 4 and the like realize the electrical signal interconnection of the first surface and the second surface of the CMOS chip 1 through the through-silicon via 13. Other signals and the power supply 4 are interconnected by the metal layers of the wafer Re-Distribution Layer 30. The number of metal layers can be adjusted according to the actual design needs, such as 2 layers, 3 layers or other number of layers.

After the image information is received by the photosensitive and microlens region 21, the CMOS chip 1 realizes photoelectric conversion to output the image data, and the image data is processed, corrected and denoised by relevant algorithms in the image processor and coder 2, and then coded, compressed and outputted to the master controller 3. The master controller 3 may store the final image data locally, upload it to an upper computer or send it through a wireless transmitter according to application needs. The control system realizes the control and management of the entire microminiature image acquisition and processing system package through a bus such as an I2C bus, an SPI bus or a GPIO wire.

### Embodiment 1

Taking two metal layers as an example, as shown in FIG. 1, a microminiature image acquisition and processing system package structure includes: optical coated glass 5, a first surface of the optical coated glass 5 being provided with a protective film 9, a cofferdam 7 being formed around a second surface of the optical coated glass 5; a CMOS chip 1, a first surface of the CMOS chip 1 being provided with a photosensitive and microlens region 21 and a metal bonding pad 9, a through-silicon via 13 being etched in a second surface of the CMOS chip 1 until it extends to the metal bonding pad 9, the cofferdam 7 being seamlessly connected to the metal bonding pad 9 and an edge region around the CMOS chip 1 through an adhesive film 8 and covering the first surface of the CMOS chip 1 to form a cavity 6, the photosensitive and microlens region 21 being located in the cavity 6; a wafer Re-Distribution Layer 30, a first layer of the wafer Re-Distribution Layer covering the second surface of the CMOS chip 1 and extending to the through-silicon via 13 region, an image processor and coder 2, a master controller 3, a power supply 4 and a connecting board 11 being disposed on the outermost layer of the wafer Re-Distribution Layer 30; and a molding layer 10, the molding layer 10 being configured to perform molding on the second surface of the CMOS chip 1, a solder ball 12 being disposed outside the molding layer 10 and corresponding to the position of the connecting board 11 with each other.

When there are two metal layers, namely the first metal layer 15 and the second metal layer 17, and three passivation layers, namely the first passivation layer 14, the second passivation layer 16 and the third passivation layer 18, the first passivation layer 14 covers the second surface of the CMOS chip 1 and extends to the through-silicon via 13 region, the first metal layer 15 covers the first passivation layer 14, and the second passivation layer 16, the second metal layer 17 and the third passivation layer 18 sequentially cover the first metal layer 15.

In order to make the image processor and coder 2, the master controller 3, the power supply 4 and other units more secure and stable, the connecting board 11 is higher than the image processor and coder 2, the master controller 3, the power supply 4 and other units, respectively.

The protective film 19 on the first surface of the optical coated glass 5 is made of a metal, a polymer or a mixture of the metal and the polymer. Here, there are no requirements for metal materials or polymer materials, and the protective film is used to protect the optical coated glass during processing and transportation, thereby resisting dust and scratch.

### Embodiment 2

This embodiment differs from Embodiment 1 in that: in order to reduce the plane size of the microminiature image acquisition processing system package structure, as shown in FIG. 2, a package region on the second surface of the CMOS chip 1 is designed as a stacked package, some functional chips (such as the master controller 3) using WB package may be stacked on the image processor and coder 2, and the signal interconnection is realized through a connecting wire 20, thereby further reducing the plane size of the entire package.

Exemplary Method:

A preparation method for the microminiature image acquisition and processing system package structure includes the following steps:
providing optical coated glass 5, a first surface of the optical coated glass 5 being provided with a protective film 19, a cofferdam 7 being formed around a second surface of the optical coated glass 5;
providing a CMOS chip 1, a first surface of the CMOS chip 1 being provided with a photosensitive and microlens region 21 and a metal bonding pad 9, a through-silicon via 13 being etched in a second surface of the CMOS chip 1 until it extends to the metal bonding pad 9, the cofferdam 7 being seamlessly connected to the metal bonding pad 9 and an edge region around the CMOS chip 1 through an adhesive film 8 and covering the first surface of the CMOS chip 1 to form a cavity 6, the photosensitive and microlens region 21 being located in the cavity 6;
forming a wafer Re-Distribution Layer 30, a first layer of the wafer Re-Distribution Layer 30 covering the second surface of the CMOS chip 1 and extending to the through-silicon via 13, an image processor and coder 2, a master controller 3, a power supply 4 and a connecting board 11 being disposed on the outermost layer of the wafer Re-Distribution Layer 30; and
forming a molding layer 10, the molding layer 10 being configured to perform encapsulating on the second surface of the CMOS chip 1, a solder ball 12 being disposed outside the molding layer 10 and corresponding to the position of the connecting board 11 with each other. Of course, the solder ball may also be a pad or bump, as long as it can be welded, while its shape is not limited.

According to the microminiature image acquisition and processing system package structure produced by this method, the photosensitive and microlens region 21 is located on the first surface of the CMOS chip 1, and the master controller 3, the image processor and coder 2, the power supply 4, a clock, a discrete device and other units are located on the second surface of the CMOS chip 1. The larger one of the chips such as the master controller 3 and the image processor and coder 2 are packaged in WLP or FC, and the other chips are disposed on the upper surface of the large-size chip using WB package, thereby achieving 3D die-stacking and saving the mounting area. The power supply 4, the clock, the discrete device and other units or resistance-capacitance devices are packaged in small chip packages. The master controller 3 realizes the control and management of other functional chips and image sensors through a control bus (I2C bus/SIP bus/GPIO), and provides an external data interface to send optimized and coded image information. The data bus, the control bus, the power supply 4 and the like realize the electrical signal interconnection of the first surface and the second surface of the CMOS chip 1 through the TSV (Through-Silicon Via). Other signals and the power supply 4 are interconnected by the metal layers of the wafer Re-Distribution Layer 30. The number of metal layers can be adjusted according to the actual design needs, such as 2 layers, 3 layers or other number of layers.

After the image information is received by the photosensitive and microlens region 21, the CMOS chip 1 realizes photoelectric conversion to output the image data, and the image data is processed, corrected and denoised by relevant algorithms in the image processor and coder 2, and then coded, compressed and outputted to the master controller 3. The master controller 3 may store the final image data locally, upload it to an upper computer or send it through a wireless transmitter according to application needs. The control system realizes the control and management of the entire microminiature image acquisition and processing system package through a bus such as an I2C bus, an SPI bus or a GPIO.

### Embodiment 3

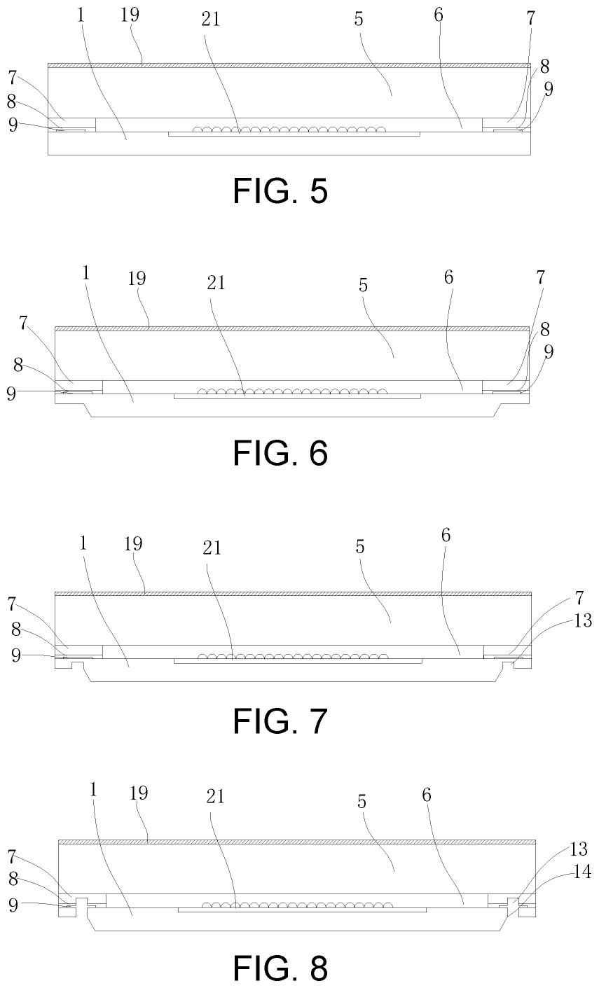

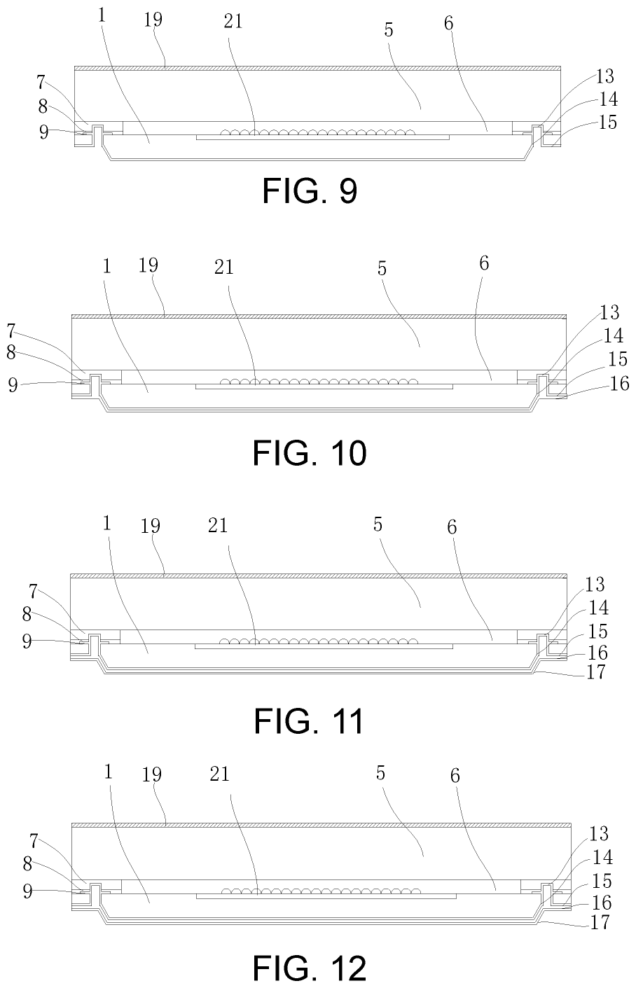

Taking two metal layers as an example, a preparation method for the microminiature image acquisition and processing system package structure includes the following steps:
providing optical coated glass 5, as shown in FIG. 3, a cofferdam 7 being formed around a second surface of the optical coated glass 5;
providing a CMOS chip 1, as shown in FIG. 4, a first surface of the CMOS chip 1 being provided with a photosensitive and microlens region 21 and a metal bonding pad 9, a through-silicon via 13 being etched in a second surface of the CMOS chip 1 until it extends to the metal bonding pad 9, the cofferdam 7 being connected to the metal bonding pad 9 and an edge region around the CMOS chip 1 through an adhesive film 8, covering the first surface of the CMOS chip 1 to form a cavity 6 which may be sealed by the adhesive film 8, the photosensitive and microlens region 21 being located in the cavity 6;
as shown in FIG. 5, forming a protective film 19 on a first surface of the optical coated glass 5;
as shown in FIGS. 6 to 12, forming a through-silicon via 13 region on the second surface of the CMOS chip 1, the through-silicon via 13 sequentially passing through the CMOS chip and the metal bonding pad 9 and extending into the cofferdam 7; and
forming a wafer Re-Distribution Layer 30, the wafer Re-Distribution Layer 30 including two metal layers, namely the first metal layer 15 and the second metal layer 17, and three passivation layers, namely the first passivation layer 14, the second passivation layer 16 and the third passivation layer 18, wherein the first passivation layer 14 covers the second surface of the CMOS chip 1 and extends to the through-silicon via 13 region; the first metal layer 15 covers the first passivation layer 14 and extends into the through-silicon via, such that the first surface and the second surface of the CMOS chip 1 are electrically connected; and the second passivation layer 16, the second metal layer 17 and the third passivation layer 18 sequentially cover the first metal layer 15.

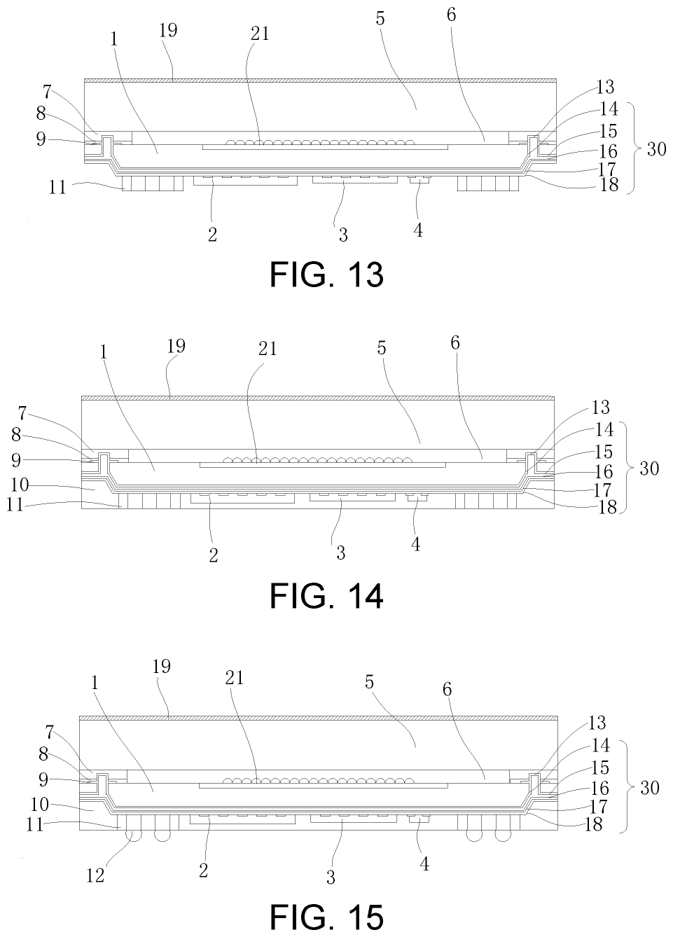

A specific process of forming the wafer Re-Distribution Layer 30 is as follows: the second surface of the CMOS chip 1 is passivated and patterned for the first time to form the first passivation layer 14, and the first passivation layer 14 partially extends to part of the through-silicon via 13 region;
the first metal layer 15 is generated on the first passivation layer 14, and the first metal layer 15 is electrically connected to the metal bonding pad 9 through the through-silicon via 13;
the first metal layer 15 is then passivated and patterned for the second time to form the second passivation layer 16;
the second metal layer 17 is generated on the second passivation layer 16;
the second metal layer 17 is passivated and patterned for the third time to form the third passivation layer 17, and the second metal layer 17 is partially exposed;
as shown in FIG. 13, the image processor and coder 2, the master controller 3, the power supply 4 and the connecting board 11 are mounted on the outermost layer (i.e., the third passivation layer 18 and the partially exposed second metal layer 17) of the wafer Re-Distribution Layer 30, and are electrically connected through the wafer Re-Distribution Layer 30 and the CMOS chip 1; and
as shown in FIG. 14, a molding layer 10 is formed, the molding layer 10 being configured to perform molding on the second surface of the CMOS chip 1. As shown in FIG. 15, a solder ball 12 is disposed outside the molding layer 10 and at a corresponding position of the connecting board 11 and being used for achieving external connection.

In addition, in one embodiment, the method further includes the following steps:
performing film-insert encapsulating or conventional encapsulating on the molding layer 10 and then grinding to expose the connecting board 11; and mounting the solder ball 12 on the connecting board 11, cutting the plate, and performing final test (this step is not shown).

### Embodiment 4

This embodiment differs from Embodiment 3 in that: in order to reduce the plane size of the microminiature image acquisition processing system package, as shown in FIG. 2, the second surface region of the CMOS chip 1 is designed as a stacked package, some functional chips (such as the master controller 3) using WB package may be stacked on the image processor and coder 2, and the signal interconnection is realized through WB, thereby further reducing the plane size of the entire package.

Further, it should be noted that shapes and names of parts and components in the specific embodiments described in the present description may be different. Any equivalent or simple changes in the structures, features and principles described in the patent conception of the present invention are included in the scope of protection of the present invention. A person skilled in the art to which the present invention belongs may make various modifications or additions to the specific embodiments described or replace them in a similar manner, which shall fall within the scope of protection of the present invention as long as they do not deviate from the structures of the invention or go beyond the scope defined in the present claims.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A microminiature image acquisition and processing system package structure, comprising:
optical coated glass, a first surface of the optical coated glass being provided with a protective film, a cofferdam being formed around a second surface of the optical coated glass;
a CMOS chip, a first surface of the CMOS chip being provided with a photosensitive and microlens region and a metal bonding pad, a through-silicon via is etched in a second surface of the CMOS chip until it extends to the metal bonding pad on the first surface of the CMOS chip, the cofferdam being seamlessly connected to the metal bonding pad and an edge region around the CMOS chip through an adhesive film and covering the first surface of the CMOS chip to form a cavity, the photosensitive and microlens region being located in the cavity;
a wafer Re-Distribution Layer, a first layer of the wafer Re-Distribution Layer covering the second surface of the CMOS chip and extending to a through-silicon via region, an image processor and coder, a master controller, a Flash, a power supply and a connecting board being disposed on an outermost layer of the wafer Re-Distribution Layer; and
a molding layer, the molding layer being configured to perform encapsulating on the second surface of the CMOS chip, a solder ball being disposed outside the molding layer and corresponding to a position of the connecting board with each other.

2. The microminiature image acquisition and processing system package structure according to claim 1, wherein the wafer Re-Distribution Layer comprises passivation layers and metal layers, which are bonded to each other; a number of the passivation layers is greater than that of the metal layers by one layer; and
the first layer of the wafer Re-Distribution Layer is one passivation layer of the passivation layers, and the outermost layer of the wafer Re-Distribution Layer is another passivation layer of the passivation layers.

3. The microminiature image acquisition and processing system package structure according to claim 2, wherein the metal layers comprises a first metal layer and a second metal layer; and the passivation layers comprises a first passivation layer, a second passivation layer and a third passivation layer; and
the first passivation layer covers the second surface of the CMOS chip and extends to the through-silicon via region, the first metal layer covers the first passivation layer and extends into the through-silicon via so that the first surface and the second surface of the CMOS chip are electrically connected, and the second passivation layer, the second metal layer and the third passivation layer sequentially cover the first metal layer.

4. The microminiature image acquisition and processing system package structure according to claim 2, wherein a number of the metal layers is three or more, and a number of the passivation layers is four or more.

5. The microminiature image acquisition and processing system package structure according to claim 1, wherein the protective film is made of a metal, a polymer or a mixture of the metal and the polymer.

6. The microminiature image acquisition and processing system package structure according to claim 1, wherein the connecting board is higher than the image processor and coder, the master controller, the Flash, and the power supply, respectively.

7. The microminiature image acquisition and processing system package structure according to claim 2, wherein the image processor and coder, the master controller, the Flash, and the power supply are designed by means of flip chip or wire bonding and stacking, and are communicated through the metal layers or by means of metal wire bonding.

8. A preparation method for the microminiature image acquisition and processing system package structure, comprising the following steps:
providing optical coated glass, a first surface of the optical coated glass being provided with a protective film, a cofferdam being formed around a second surface of the optical coated glass;
providing a CMOS chip, a first surface of the CMOS chip being provided with a photosensitive and microlens region and a metal bonding pad, a through-silicon via being etched in a second surface of the CMOS chip until it extends to the metal bonding pad on the first surface of the CMOS chip, the cofferdam being seamlessly connected to the metal bonding pad and an edge region around the CMOS chip through an adhesive film and covering the first surface of the CMOS chip to form a cavity, the photosensitive and microlens region being located in the cavity;
forming a wafer Re-Distribution Layer, a first layer of the wafer Re-Distribution Layer covering the second surface of the CMOS chip and extending to a through-silicon via region, an image processor and coder, a master controller, a Flash, a power supply and a connecting board being disposed on an outermost layer of the wafer Re-Distribution Layer; and
forming a molding layer, the molding layer being configured to perform encapsulating on the second surface of the CMOS chip, a solder ball being disposed outside the molding layer and corresponding to a position of the connecting board with each other.

9. The preparation method for the microminiature image acquisition and processing system package structure according to claim 8, wherein the wafer Re-Distribution Layer comprises passivation layers and metal layers, which are bonded to each other; a number of the passivation layers is greater than that of the metal layers by one layer; and
the first layer of the wafer Re-Distribution Layer is one passivation layer of the passivation layers, and the outermost layer of the wafer Re-Distribution Layer is another passivation layer of the passivation layers.

10. The preparation method for the microminiature image acquisition and processing system package structure according to claim 9, wherein the metal layers comprises a first metal layer and a second metal layer; and the passivation layers comprises a first passivation layer, a second passivation layer and a third passivation layer; and
the first passivation layer covers the second surface of the CMOS chip and extends to part of the through-silicon via region, the first metal layer covers the first passivation layer and extends into the through-silicon via so that the first surface and the second surface of the CMOS chip are electrically connected, and the second passivation layer, the second metal layer and the third passivation layer sequentially cover the first metal layer.

11. The preparation method for the microminiature image acquisition and processing system package structure according to claim 10, wherein
the second surface of the CMOS chip is passivated and patterned for a first time to form the first passivation layer;
the first metal layer is generated on the first passivation layer;
the first metal layer is then passivated and patterned for a second time to form the second passivation layer;
the second metal layer is generated on the second passivation layer; and
the second metal layer is passivated and patterned for a third time to form the third passivation layer.

12. The preparation method for the microminiature image acquisition and processing system package structure according to claim 11, wherein
the image processor and coder, the master controller, the Flash, the power supply and the connecting board are mounted on the outermost layer of the wafer Re-Distribution Layer or connected thereto via a conductive structure.

13. The preparation method for the microminiature image acquisition and processing system package structure according to claim 9, wherein
the second surface of the CMOS chip is passivated and patterned for a first time to form the first passivation layer;
the first metal layer is generated on the first passivation layer;
the first metal layer is then passivated and patterned for a second time to form the second passivation layer;
the second metal layer is generated on the second passivation layer; and
the second metal layer is passivated and patterned for a third time to form the third passivation layer.

14. The preparation method for the microminiature image acquisition and processing system package structure according to claim 13, wherein
the image processor and coder, the master controller, the Flash, the power supply and the connecting board are mounted on the outermost layer of the wafer Re-Distribution Layer or connected thereto via a conductive structure.

15. The preparation method for the microminiature image acquisition and processing system package structure according to claim 9, wherein the image processor and coder, the master controller, the Flash, and the power supply are designed by means of flip chip or wire bonding and stacking, and are communicated by the metal layers or by means of metal wire bonding.

16. The preparation method for the microminiature image acquisition and processing system package structure according to claim 8, further comprising the following steps:
performing encapsulating on the molding layer and then grinding to expose the connecting board; and
mounting the solder ball on the connecting board, cutting the connecting board, and performing final test.
